(19) United States
(12) Patent Application Publication
(10) Pub. No.: US 2019/0013496 A1
(43) Pub. Date: Jan. 10, 2019

(54) MULTIFUNCTIONAL HIERARCHICAL NANO AND MICROLENS FOR ENHANCING EXTRACTION EFFICIENCY OF OLED LIGHTING

(71) Applicant: SABIC Global Technologies B.V., Bergen op Zoom (NL)

(72) Inventors: Sang Hoon KIM, Seoul (KR); Hoo Keun PARK, Seoul (KR)

(21) Appl. No.: 16/064,230

(22) PCT Filed: Dec. 28, 2016
(86) PCT No.: PCT/IB2016/058058

§ 371 Date: Jun. 20, 2018

Related U.S. Application Data
(60) Provisional application No. 62/273,756, filed on Dec. 31, 2015.

(51) Int. Cl. H01L 51/52; G02B 1/118; H01L 51/56; G03F 7/00

(52) U.S. Cl. CPC H01L 51/5275; G02B 1/118; H01L 2251/558; G03F 7/0002; G02B 2207/101; H01L 51/56

(57) ABSTRACT

The process includes forming an imprinting template having patterning features, imprinting a polymeric material with the imprinting template, and removing the imprinting template to form the nano-patterned microlens. The process of forming an imprinting template includes preparing a self-assembled monolayer on a support substrate, forming a patterned support substrate, wherein the patterned support substrate includes patterning features corresponding to the imprinting template and fabricated nano-patterned microlens, applying a liquid resin composition to the patterned support substrate and curing the resin composition and removing the patterned support substrate from the cured resin composition.

### TECHNICAL FIELD

The present disclosure relates to a light emitting devices, and more particularly to organic light emitting devices and microlens arrays for enhancing the extraction efficiency thereof.

### BACKGROUND

Today, organic light emitting devices/diodes (OLEDs) are increasingly used in lighting applications because they are more energy efficient than other conventional lighting sources. OLEDs typically have a stacked structure composed of one or more organic layers positioned between two electrodes, e.g. a cathode and an anode. The organic layers in an OLED are often composed of electroluminescent polymers that emit light when a voltage is applied across the anode and the cathode. At least one of the two electrodes, either the anode or the cathode electrode is formed from a transparent conductive material, which enables the light emitted from the OLED to be visible.

Generally, the extraction efficiency of OLEDs is quite low because of differences in the refractive indices between air, the substrate, and the organic/electrode layers. Improving extraction efficiency is critical because higher extraction will yield additional energy savings, prolong the lifetime of the device and increase cost savings. Improving extraction efficiency, however, remains a significant challenge for lighting applications using OLEDs.

Microlens array structures contain multiple microlenses formed in a one-dimensional or two-dimensional array on a supporting substrate. Microlens array structures are typically used to improve the extraction efficiency of light captured between air and the substrate. Microlenses with various heights and diameters have been used and the enhancement value of extraction efficiency from OLED device has substantially improved. Furthermore, super-hydrophobicity (for anti-dust and barrier effect), anti-glare and anti-reflective effects are also desired properties for many applications. Therefore, if one substrate with multi-function is developed, then it could meet the various requirements such as low cost, thin thickness, and high efficiency.

Thus, there is a need for microlenses for OLEDs that provide improved extraction efficiency in combination with other desirable properties such as super-hydrophobicity and anti-glare properties. Accordingly, the disclosed nano-patterned microlenses and processes are directed at overcoming one or more of these disadvantages in currently available OLEDs.

### SUMMARY

In accordance with one aspect of the disclosure, a process of fabricating a nano-patterned microlens is disclosed. The process includes forming an imprinting template having patterning features, imprinting a polymeric material with the imprinting template, and removing the imprinting template to form the nano-patterned microlens. Forming an imprinting template includes preparing a self-assembled monolayer on a support substrate, forming a patterned support substrate, wherein the patterned support substrate includes patterning features corresponding to the imprinting template and fabricated nano-patterned microlens, applying a liquid resin composition to the patterned support substrate and curing the resin composition; and removing the patterned support substrate from the cured resin composition.

In accordance with another aspect of the disclosure, a process of fabricating a nano-patterned microlens is disclosed. The process includes forming an imprinting template having patterning features, imprinting a microlens with the imprinting template; and removing the imprinting template to form the nano-patterned microlens. The process of forming the imprinting template includes depositing a silicon dioxide film on a substrate, preparing a self-assembled monolayer on the silicon dioxide film, wherein the monolayer comprises a plurality of nanospheres, removing portions of the nanospheres in the self-assembled monolayer to form a reduced substrate, applying a photolithographic mask to the reduced substrate to form a patterned substrate, applying a liquid resin to the patterned substrate and curing the resin and removing the patterned substrate from the cured resin.

### BRIEF DESCRIPTION OF THE DRAWINGS

The above-mentioned and other features and advantages of this disclosure, and the manner of attaining them, will become apparent and be better understood by reference to the following description of one aspect of the disclosure in conjunction with the accompanying drawings, wherein:

FIG. 1(A) is a Fast Scanning Electron Microscope (FSEM) photograph of a conventional microlens.

FIG. 1(B) is a schematic perspective view of a multifunctional hierarchical nano and microlens structure according to one aspect of the present disclosure.

FIGS. 2(A)-(I) are schematic perspective views of the process steps used to fabricate the multifunctional hierarchical nano and microlens structure according to one aspect of the present disclosure.

FIGS. 3(A)-(P) are schematic perspective views of the process steps used to fabricate the multifunctional hierarchical nano and microlens structure according to one aspect of the present disclosure.

FIG. 4 is a schematic illustration of the nano lens array on the substrate according to one aspect of the present disclosure.

FIG. 5 is a Fast Scanning Electron Microscope (FSEM) photograph of buckling structures on the substrate according to one aspect of the present disclosure.

### DETAILED DESCRIPTION

### Nano-Patterned Microlens

The present disclosure provides nano-patterned microlenses and processes of fabricating nano-patterned microlenses. The nano-patterned microlens disclosed herein has a structure that includes a microlens or a micro mold having a surface that is nano-patterned with nano-sized features. The term “nano-patterned” as used with regard to the present disclosure refers to very small patterning that is provided on a surface of a microlens or micromold. The patterning has structural features or nano-features whose size can be appropriately measured on a nanometer scale (10⁻⁹ meters), for example, sizes ranging from 100 nm to few microns.

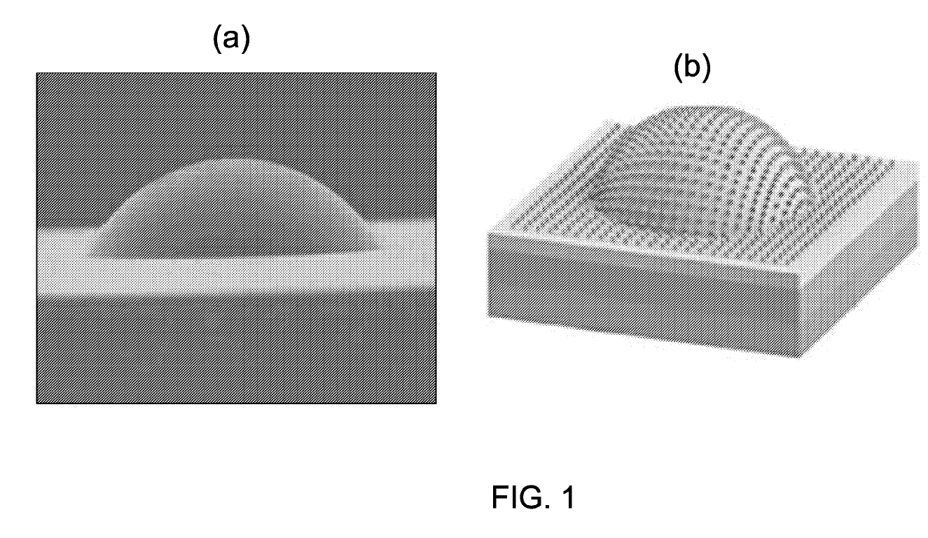

FIG. 1(A) shows a FSEM photograph of a conventional microlens. As shown, the conventional microlens generally has a spherical profile and a smooth surface profile that does not include any structural features. FIG. 1(B) illustrates a perspective view of a nano-patterned microlens structure according to one aspect of the present disclosure. As shown, the spherical microlens structure is maintained, but the surface of the microlens is nano-patterned or patterned with structural features that are nano-sized.

The nano-patterned microlenses are typically provided on the substrate of an OLED to reduce the amount of light lost due to the internal reflection at the substrate to air interface. As a result, the nano-patterned microlenses disclosed herein may be useful to improve the extraction efficiency of an OLED. The nano-patterned microlens may also provide anti-glaring and super hydrophobic properties to the OLED.

In some aspects of the disclosure, there may be a plurality of microlenses used in an OLED. The nano-patterned microlenses disclosed herein may be disposed over the substrate of the OLED. In some aspects, the nano-patterned microlenses may be disposed over the light-emitting side of the substrate. The nano-patterned microlenses may also be coupled to the OLED. For example, the nano-patterned microlens of the present disclosure may be coupled to the organic light-emitting layer of the OLED. The OLED described herein may include an anode, a cathode, and an organic emitting layer disposed between the anode and the cathode.

### Fabrication Process for Nano-Patterned Microlens

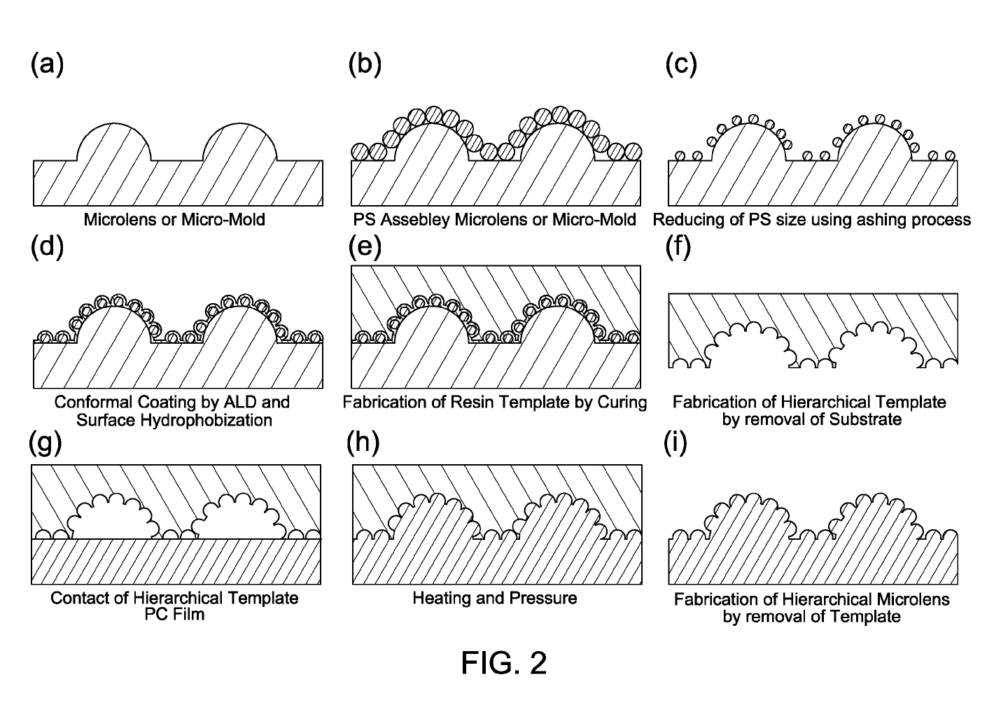

FIGS. 2(A)-(I) show a schematic illustration of a process of fabricating a nano-patterned microlens according one aspect of the present disclosure. The starting point in the fabrication process is fabrication of an imprinting template, which is then used to fabricate the nano-patterned microlens. FIGS. 2(A)-(F) illustrate the steps used to fabricate the imprinting template. As shown, a support substrate is provided. The support substrate is shown in FIG. 2(A) as a conventional microlens. A micro-mold, however, may also be used. It should also be noted that the disclosure is not limited to using microlenses with a generally spherical profile as shown in FIG. 2(A). Microlenses having nonspherical or irregular profiles may also be used if desired.

In the next step, a self-assembled monolayer is provided on the surface of the support substrate. In some aspects, according to the disclosure provided herein, the self-assembled monolayer may be composed of nanospheres. Organic polymer materials, inorganic materials and combinations thereof may be prepared into nanospheres. These nanomaterials may be used to form closely-packed, layered structures of one or several layers on suitable supports. A compact, well-defined layer structure may be readily formed.

In some aspects of the disclosure, the nanospheres may be polymer nanospheres, such as polystyrene and/or polymethyl methacrylate. Other suitable polymers may be used and the disclosure is not limited in this regard. In other aspects, the nanospheres may include inorganic nanospheres such as silicon dioxide.

The nanospheres in the monolayer may be uniform or non-uniform in size. In some aspects of the disclosure, the nanospheres may have diameters ranging from 20 nm to 1000 nm. In some aspects of the disclosure, the nanospheres may have diameters ranging from 100 nm to 500 nm. In some aspects of the disclosure, the nanospheres may have diameters ranging from 200 nm to 300 nm. The self-assembled monolayer may for example be composed of polystyrene nanospheres that have diameters ranging from 20 nm to 1000 nm. In some aspects, the self-assembled monolayer may be composed of polystyrene nanospheres that have diameters ranging from 100 nm to 500 nm. In other aspects, the self-assembled monolayer may be composed of polystyrene nanospheres that have diameters ranging from 200 nm to 300 nm.

According to one aspect of the disclosure, the self-assembled monolayer may be initially formed as a self-supporting film. For example, the self-assembled monolayer may be formed as a self-supporting film on the surface of water. The self-assembled monolayer may then be separated from the water surface and transferred to support substrate as needed by using a scooping technique. The self-assembled monolayer may scooped from the water surface and deposited on the surface of the support substrate. In some aspects, a mesh material may be used to transfer the self-assembled monolayer from the water to the support substrate.

In the next step shown in FIG. 2(C), the self-assembled monolayer is reduced to form a patterned support substrate. In this reduction step, portions of the self-assembled monolayer are removed to form the patterned support substrate. In one aspect of the disclosure, a plasma ashing process may be used to reduce the nanospheres in the self-assembled monolayer. In another aspect of the disclosure, the plasma ashing process may use a source of oxygen. The plasma ashing process may remove a portion of the self-assembled monolayer such that the diameter of the nanospheres is reduced. The reduction in the self-assembled monolayer may define a plurality of interstitial spaces between the nanospheres in the monolayer. As set forth in further detail below, a conformal coating may be subsequently deposited on the reduced self-assembled monolayer, including within the interstitial spaces of the self-assembled monolayer.

Plasma ashing processes for removing polymers and/or residues from a substrate are well known to those skilled in the art. In one aspect, the plasma ashing process may include placing the self-assembled monolayer on the support substrate in a suitable reaction chamber, generating a plasma from an oxygen containing gas and exposing the self-assembled monolayer on the support substrate to selectively remove the polymers, and/or residues from the support substrate. The patterned support substrate resulting from the plasma ashing has patterning features corresponding to the imprinting template and the fabricated nano-patterned microlens.

### Conformal Coating

In the next step shown in FIG. 2(D), a conformal coating is deposited onto the patterned support substrate. The conformal coating may be deposited on the reduced self-assembled monolayer, including within the interstitial spaces in the monolayer that were formed from the plasma ashing process. In some aspects, the conformal coating may be composed of a metal oxide.

The metal oxide may be light-transmitting. The metal oxide in some aspects may be a compound stable against light, oxygen and heat, such as ZnO, SiO₂, Al₂O₃, ZrO₂, SnO₂, TiO₂, or CaO. In some aspects, an oxide of at least one metal selected from the group consisting of Si, Ti, Al and Zr may be used. In some aspects, SiO₂, Al₂O₃, TiO₂, or ZrO₂ may be preferred as metal oxides. The thickness of the metal oxide layer deposited as the conformal coating is preferably from 1 to 10 nm, particularly preferably from 2 to 8 nm on the average. In some aspects of the disclosure, the conformal coating is deposited using chemical vapor deposition or atomic layer deposition.

### Hydrophobic Surface Treatment

FIG. 2(D) further illustrates that a hydrophobic surface treatment may be applied to the patterned support substrate. The hydrophobic surface treatment may be applied to the patterned support substrate after the conformal coating has been deposited. The hydrophobic surface treatment may also be applied at the same time the conformal coating is deposited on the patterned support substrate.

The hydrophobic surface treatment may be used to produce a surface of the patterned support substrate that is hydrophobic. Any hydrophobic surface treatment may be used to impart hydrophobic properties to the surface of the patterned support substrate. In one aspect of the disclosure, the hydrophobic surface treatment may be composed of an organic silane, such as an alkylsilane. The hydrophobic surface treatment may be applied to the patterned substrate using chemical vapor deposition. In some aspects of the disclosure, the hydrophobic surface of the patterned support substrate may be obtained by forming a self-assembled monolayer through chemical vapor deposition with an alkylsilane.

### Fabrication of the Imprinting Template

In the next step shown in FIG. 2(E), a curable liquid resin may be applied to the patterned support substrate. Suitable curable liquid resins may include, but are not limited to polydimethylsiloxane (PDMS), polyurethane, polyolefins, epoxy resins, polyester resins, phenolic resins, and combinations thereof. After the curable liquid resin is applied to the patterned support substrate, the curable liquid resin may be cured using radiation or UV light.

As shown in FIG. 2(F), the patterned support substrate is then removed from the cured resin. The removal of the patterned support substrate from the cured resin forms an imprinting template having certain patterning features.

### Nano-Imprinting Method

Once the imprinting template has been formed, the template may be used to form the nano-patterned microlens by a nano-imprinting method. The nano-imprinting method is schematically illustrated in FIGS. 2(G)-2(I). As shown in FIG. 2(G), the imprinting template is contacted with a polymeric material. The polymeric material used in the nano-imprinting method is ultimately the material constituting the fabricated nano-patterned microlens. In one aspect of the disclosure, the polymeric material constituting the fabricated nano-patterned microlens may be transparent or translucent. Transparent and/or translucent polymeric materials may transmit light and therefore may be useful in forming an OLED that ultimately incorporates the nano-patterned microlens. In some aspects, the nano-patterned microlens may be used as a substrate for an OLED.

Suitable polymeric materials may include, but are not limited to a thermosetting resin, a thermoplastic resin or a photocurable resin composition. The thermosetting resin may, for example, be a polyimide (PI), an epoxy resin or a urethane resin. The thermoplastic resin may, for example, be polypropylene (PP), polyethylene (PE), polyethylene terephthalate (PET), polymethyl methacrylate (PMMA), a cycloolefin polymer (COP), a cycloolefin copolymer (COC), or a transparent fluororesin.

In one aspect of the disclosure, the polymeric material may be a polycarbonate (PC) material. In another aspect of the disclosure, the polymeric material may be in the form of a polymeric film. In some aspects, the polymeric film may be a polycarbonate film. The polymeric film may be applied to a substrate to assist with manipulating the polymeric film as it is heated and pressure is applied during the nano-imprinting method.

As shown in FIG. 2(H), the fabrication process further includes compressing the imprinting template at a predetermined temperature under a predetermined pressure to imprint the polymeric material with the imprinting template. Compression of the imprinting template with the polymeric material may result in direct mechanical deformation of the polymeric material to achieve the desired nano-patterned definition of the microlens. In some aspects, the predetermined temperature may range from 50 C to 200 C. In other aspects, the predetermined pressure may range from 10 bar to 50 bar. The predetermined temperature and predetermined pressure used in the nanoimprinting method is a function at least in part of the polymeric material selected in the process. For example, the predetermined temperature and pressure may be the temperature and pressure at which mechanical deformation of the polymeric material occurs, i.e., above the glass transition temperature. The predetermined temperature and pressure may be maintained until it is certain that the polymeric material fills the cavities in the imprinting template. The nanopatterns are created by the mechanical deformation of the polymer material using the imprinting template.

As shown in FIG. 2(I), the fabrication process may further include removal of the imprinting template to form the nano-patterned microlens. Once a sufficient amount of pressure has been applied to the imprinting template and microlens for a sufficient period of time, the microlens may be cooled and the pressure may be released. In some aspects of the disclosure, the microlens and/or the imprinting template may include a release layer if needed. The release layer, however, is not required.

### Fabrication Process Using Nanoholes

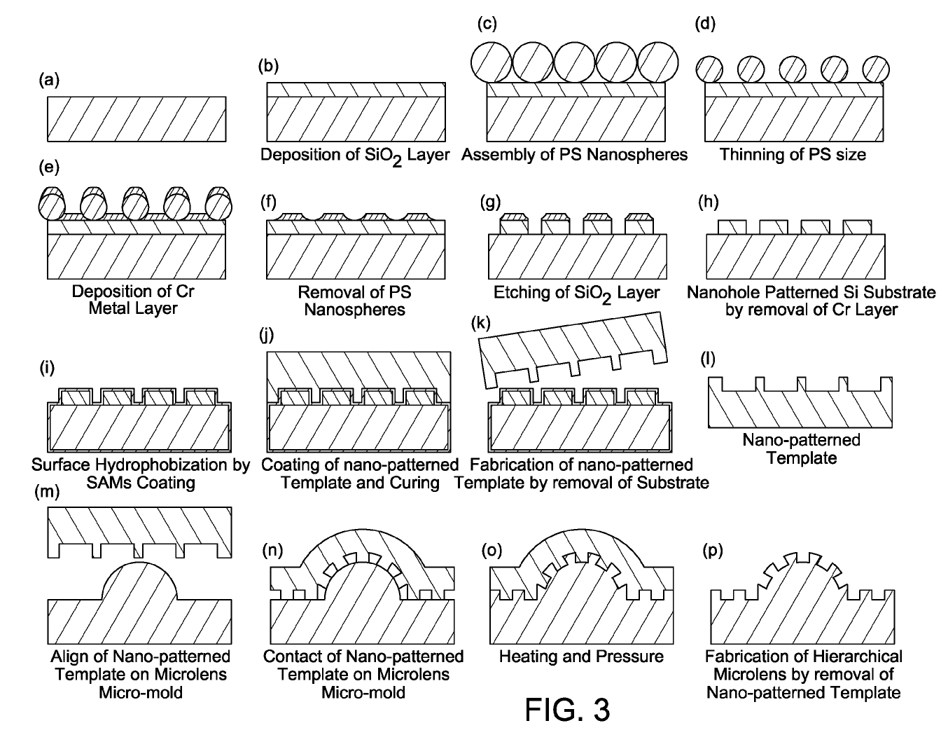

Referring now to FIGS. 3(A)-(P), a schematic illustration of a process of fabricating a nano-patterned microlens according another aspect of the present disclosure is shown. According to this aspect of the disclosure, the fabrication process includes nanosphere lithography (NSL), reactive ion etching process (RIE) and nano-imprinting methods. Again, the starting point in the fabrication process is fabrication of an imprinting template, which is then used to fabricate the nano-patterned microlens. FIGS. 3(A)-(L) illustrate the steps used to fabricate the imprinting template according to one aspect of the disclosure.

### Nanosphere Lithography Process

As shown in FIG. 3(A), a support substrate is provided. According to one aspect of the disclosure, the support substrate is a silicone-containing substrate. In the next step shown in FIG. 3(B), a silicon dioxide film is deposited on the support substrate. In some aspects, the silicon dioxide film is deposited on a silicon-containing substrate. The silicon dioxide film may be deposited on the silicon-containing substrate by plasma enhanced chemical vapor deposition.

In the next step shown in FIG. 3(C), a self-assembled monolayer is formed on the surface of the silicon dioxide layer of the support substrate. The self-assembled monolayer may be composed of nanospheres, in particular polymer nanospheres such as polystyrene nanospheres. Organic polymer materials, inorganic materials and combinations thereof may also be prepared into nanospheres. The nanospheres may form closely-packed, layered structures of one or several layers on the silicon-containing substrate as shown in FIG. 3(C). In one aspect according to the disclsoure, the self-assembled monolayer may be used as a deposition mask.

The nanospheres in the monolayer may be uniform or non-uniform in size. In some aspects of the disclosure, the nanospheres may have diameters ranging from 20 nm to 1000 nm. In some aspects of the disclosure, the nanospheres may have diameters ranging from 100 nm to 500 nm. In some aspects of the disclosure, the nanospheres may have diameters ranging from 200 nm to 300 nm. The self-assembled monolayer may for example be composed of polystyrene nanospheres that have diameters ranging from 20 nm to 1000 nm. In some aspects, the self-assembled monolayer may be composed of polystyrene nanospheres that have diameters ranging from 100 nm to 500 nm. In other aspects, the self-assembled monolayer may be composed of polystyrene nanospheres that have diameters ranging from 200 nm to 300 nm.

The self-assembled monolayer may be initially formed as a self-supporting film as described herein. For example, the self-assembled monolayer may be formed as a self-supporting film on the surface of water and then be separated from the water surface and transferred to support substrate as needed by using a scooping technique.

In the next step shown in FIG. 3(D), the self-assembled monolayer is reduced or thinned to form a reduced substrate. In this reduction step, portions of the self-assembled monolayer are removed to form the patterned support substrate. In one aspect of the disclosure, a plasma ashing process may be used to reduce the nanospheres in the self-assembled monolayer. The plasma ashing process may use a source of oxygen. The plasma ashing process may remove a portion of the self-assembled monolayer such that the diameter of the nanospheres is reduced. In another aspect of the disclosure, a reactive ion etch process using oxygen gas may be used to reduce the nanospheres and form the reduced substrate. The reduction in the self-assembled monolayer may define a plurality of interstitial spaces between the nanospheres in the monolayer.

FIG. 3(E) illustrates the next step in which a chromium layer is deposited on the reduced substrate. As shown, FIG. 3(E), the chromium layer is deposited on the surface of the reduced substrate, including within the interstitial spaces of the reduced substrate. In some aspects, the chromium layer may be deposited on the reduced substrate using a thermal evaporator. After depositing the chromium layer on the reduced substrate, the nanospheres are removed as shown in FIG. 3(F). Removal of the nanospheres from the chromium layer results in the formation of a layer of chromium nanoholes on the reduced substrate. The nanoholes are used to form the resulting nano-patterned microlens as described herein.

### Reactive Ion Etch Process

After the plurality of nanoholes is formed in the reduced substrate, portions of the silicon dioxide film are removed from the reduced substrate. As shown in FIG. 3(G), the reduced substrate has portions that contain the chromium metal film and portions that do not contain any of the chromium metal film. As shown in FIG. 3(G), the portions of the silicon dioxide film that do not contain the chromium metal layer are etched away from the reduced substrate. In some aspects of the disclosure, the silicon dioxide layer may be etched using a reactive ion etch process. In one aspect, the reactive ion etch process may be a tetraflouro-methane (CF₄) based process. In the next step shown in FIG. 3(H), the remaining portion of the chromium metal layer is removed using a wet etching process to form a patterned substrate.

### Fabrication of the Imprinting Template

As shown in FIG. 3(I), the resulting patterned substrate may undergo a hydrophobic surface treatment as described herein. The surface hydrophobization may result in a second self-assembled monolayer on the patterned substrate as previously described. For example, an alkylsilane may be used to lower the surface energy of the patterned substrate and chemical modify the surface forming a self-assembled monolayer.

In the next step shown in FIG. 3(J), a curable liquid resin may be applied to the patterned substrate. Suitable curable liquid resins may include, but are not limited to polymethyl methacrylate, polydimethylsiloxane (PDMS), polyurethane, polyolefin, epoxy resins, polyester resins, phenolic resins, and combinations thereof. After the curable liquid resin is applied to the patterned substrate, the curable liquid resin may be cured using radiation or UV light. In one aspect, the curable resin is placed in an oven and heated at a constant temperature.

As shown in FIGS. 3(K) and 3(L), the patterned substrate is then removed from the cured resin. The removal of the patterned support substrate from the cured resin forms an imprinting template having nano-patterned features as shown in FIG. 3(L). The imprinting template may be used to pattern a microlens or a micro-mold. The imprinting template may be flexible. The imprinting template may also have nanorod features as shown in FIG. 3(L).

Nano-Imprinting the Microlens with the Imprinting Template

Once the imprinting template has been formed, the imprinting template may be used to fabricate the nano-patterned microlens. According to one aspect of the disclosure, a conventional microlens or micro-mold is nano-patterned using the imprinting template. The microlens or micro-mold may be composed of a polycarbonate or other polymer material. The microlens may be heated using a hot plate at a constant temperature. The microlens may be heated to a temperature that is higher than the glass transition temperature of the microlens.

The nano-imprinting method is schematically illustrated in FIGS. 3(M)-3(P). As shown in FIG. 3(M), the imprinting template after heating is aligned with a microlens or a micro-mold. The microlens may initially have a spherical surface structure as shown in FIGS. 3(M) and 3(N), but the nano-imprinting method may impart nano-sized features on the surface of the microlens as shown in FIGS. 3(0) and 3(P). In one aspect, the spherical microlens structure may be maintained, but the surface of the microlens is nano-patterned or patterned with structural features that are nano-sized. As shown in FIG. 3(N), the imprinting template is contacted with the surface of the microlens. The imprinting template may be flexible and able to conform to the surface of the microlens.

As shown in FIG. 3(0), the fabrication process further includes compressing the imprinting template and microlens under a predetermined pressure to imprint the microlens. Compression of the microlens with the template may result in direct mechanical deformation of the microlens to achieve the desired nano-patterned definition. In some aspects, the predetermined pressure may range from 10 bar to 50 bar. The predetermined pressure used in the nanoimprinting method is a function at least in part of the microlens selected in the process. For example, the predetermined pressure may be the pressure at which mechanical deformation of the microlens occurs. The predetermined pressure may be maintained until it is certain that the microlens material fills the cavities in the imprinting template. The nano-patterns are created by the mechanical deformation of the microlens using the imprinting template.

As shown in FIG. 3(P), the fabrication process may further include removal of the imprinting template to form the nano-patterned microlens. Once a sufficient amount of pressure has been applied to the imprinting template and microlens for a sufficient period of time, the microlens may be cooled to room temperature and the pressure may be released. In some aspects of the disclosure the template for nano imprinting may include a release layer if needed. The release layer, however, may not be required in other aspects of the disclosure.

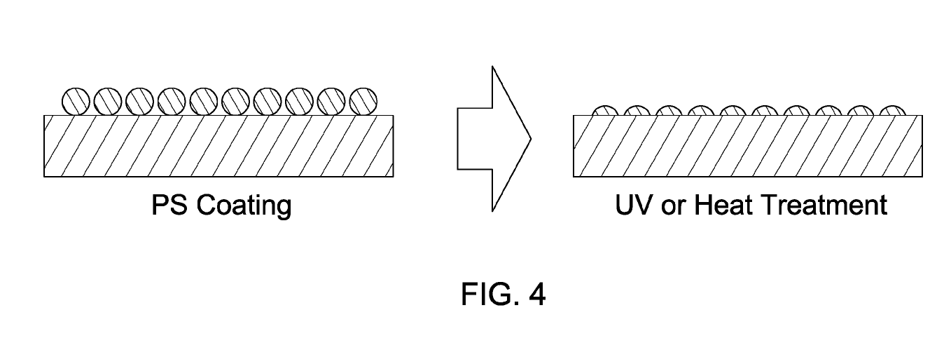

Referring now to FIG. 4, a schematic of a nanolens array formed on a substrate is shown. In one aspect of the disclosure, a nanolens array film may be fabricated without using a microlens. For example, after forming a self-assembled monolayer on the support substrate, a UV or heat treatment may be performed to form a lens shape on the support substrate. This may simplify or reduce the number of steps needed to fabricate a nano-patterned microlens.

### Buckling Layers

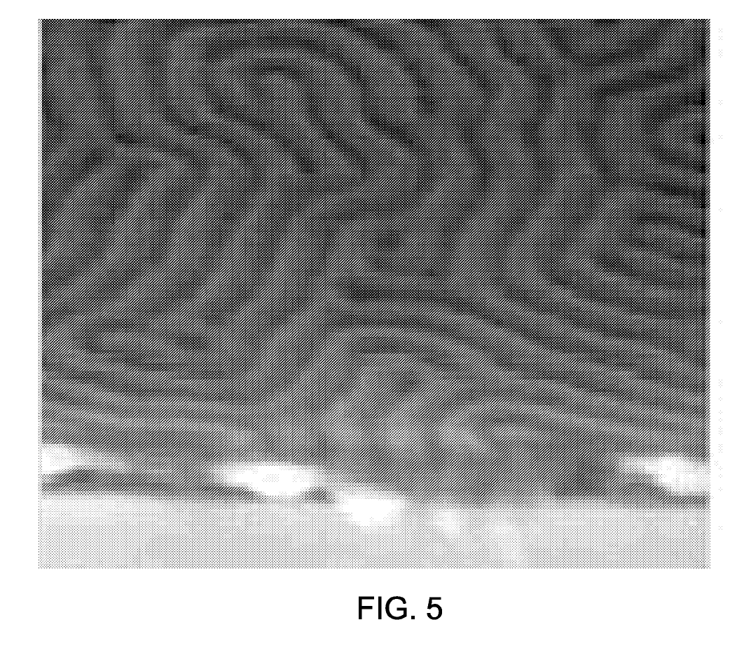

In some aspects of the present disclosure, buckling layers may be formed on the nano-patterned microlens. FIG. 5 is a FSEM photograph of buckling structures formed according to one aspect of the present disclosure. The buckling layers may include buckles, which may be used to relieve any internal stresses present in the nano-patterned microlens. The buckling layer may be deposited on the nano-patterned microlens by vacuum evaporation. In some aspects, the buckling layer may be reflective to increase the amount of light that is scattered through the various layers in the OLED structure.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

### Definitions

It is to be understood that the terminology used herein is for the purpose of describing particular aspects only and is not intended to be limiting. As used in the specification and in the claims, the term “comprising” can include the embodiments “consisting of” and “consisting essentially of.” Unless defined otherwise, all technical and scientific terms used herein have the same meaning as commonly understood by one of ordinary skill in the art to which this disclosure belongs. In this specification and in the claims, which follow, reference will be made to a number of terms, which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, alloys, reaction products, and the like.

Ranges can be expressed herein as from one particular value to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated±5% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

As used herein, the term “light” means electromagnetic radiation including ultraviolet, visible or infrared radiation.

As used herein, the term “transparent” means that the level of transmittance for a disclosed composition is greater than 50%. In some embodiments, the transmittance can be at least 60%, 70%, 80%, 85%, 90%, or 95%, or any range of transmittance values derived from the above exemplified values. In the definition of “transparent”, the term “transmittance” refers to the amount of incident light that passes through a sample measured in accordance with ASTM D1003 at a thickness of 3.2 millimeters.

As used herein, the term “layer” includes sheets, foils, films, laminations, coatings, blends of organic polymers, metal plating, and adhesion layer(s), for example. Further, a “layer” as used herein need not be planar, but may alternatively be folded, bent or otherwise contoured in at least one direction, for example.

As used herein, the term “nanosphere” is meant to encompass components or particles that are nano-sized or have a mean diameter of that ranges from 1 nm to few microns.

Unless otherwise stated to the contrary herein, all test standards are the most recent standard in effect at the time of filing this application.

### Aspects

The present disclosure comprises at least the following aspects.

Aspect 1. A process of fabricating a nano-patterned microlens, the process comprising: (a) forming an imprinting template having patterning features comprising: (i) providing a support substrate; (ii) preparing a self-assembled monolayer on the support substrate; (iii) removing portions of the self-assembled monolayer on the support substrate to form a patterned support substrate, wherein the patterned support substrate includes patterning features corresponding to the imprinting template and fabricated nano-patterned microlens; (iv) depositing a conformal coating onto the patterned support substrate; (v) applying a hydrophobic surface treatment to the patterned support substrate; (vi) applying a curable liquid resin composition to the patterned support substrate; (vii) curing the liquid resin composition; and (viii) removing the patterned support substrate from the cured resin composition thereby forming the imprint template having patterning features; and (b) contacting the imprinting template with a polymeric material; (c) compressing the imprinting template at a predetermined temperature under a predetermined pressure to imprint the polymeric material with the imprinting template; and (d) removing the imprinting template to form the nano-patterned microlens.

Aspect 2. The process of aspect 1, wherein the removing the imprinting template further comprises cooling the template and polymeric material and releasing the pressure.

Aspect 3. The process of aspects 1 or 2, wherein the preparing a self-assembled monolayer on the support substrate comprises forming the self-assembled monolayer on a water surface and transferring the monolayer from the water surface to the support substrate.

Aspect 4. The process of aspect 3, wherein the transferring the monolayer from the water surface to the support substrate includes utilizing a scooping technique.

Aspect 5. The process of any of the preceding aspects, wherein the self-assembled monolayer comprises nanospheres.

Aspect 6. The process of aspect 5, wherein the self-assembled monolayer comprises polymer nanospheres or inorganic nanospheres.

Aspect 7. The process of aspect 6, wherein the polymer nanospheres include polystyrene nanospheres.

Aspect 8. The process of aspect 6, wherein the polymer nanospheres include polymethyl methacrylate.

Aspect 9. The process of aspect 6, wherein the inorganic nanospheres comprise SiO₂.

Aspect 10. The process of aspects 5-9, wherein the nanospheres have diameters ranging from 20 nm to 1000 nm.

Aspect 11. The process of aspect 5, wherein the nanospheres include polystyrene nanospheres having diameters ranging from 20 nm to 1000 nm.

Aspect 12. The process of any of the preceding aspects, wherein the hydrophobic surface treatment comprises an alkylsilane.

Aspect 13. The process of any of the preceding aspects, wherein the conformal coating comprises a metal oxide.

Aspect 14. The process of any of the preceding aspects, wherein the support substrate is a microlens or a micro-mold.

Aspect 15. The process of any of the preceding aspects, wherein the depositing the conformal coating utilizes atomic layer deposition.

Aspect 16. The process of any of the preceding aspects, wherein the removing portions of the self-assembled monolayer utilizes a plasma ashing process with oxygen.

Aspect 17. The process of any of the preceding aspects, wherein the self-assembled monolayer comprises nanospheres and the removing the portions of the self-assembled monolayer further comprises defining a plurality of interstitial spaces between the nanospheres in the monolayer.

Aspect 18. The process of aspect 17, wherein the depositing the conformal coating includes depositing the conformal coating within the interstitial spaces.

Aspect 19. The process of any of the preceding aspects, wherein the conformal coating comprises Al₂O₃ or TiO₂.

Aspect 20. The process of any of the preceding aspects, wherein the depositing the conformal coating and applying a hydrophobic surface treatment forms a second self-assembled monolayer on the patterned support substrate.

Aspect 21. The process of any of the preceding aspects, wherein the polymeric material comprises a polycarbonate.

Aspect 22. The process of any of the preceding aspects, wherein the polymeric material is transparent.

Aspect 23. The process of any of the preceding aspects, further comprising forming a buckling layer disposed on the surface of the fabricated nano-patterned microlens.

Aspect 24. The process of any of the preceding aspects, wherein the nano-patterned microlens is used in a light-emitting device.

Aspect 25. The process of any of the preceding aspects, wherein the nano-patterned microlens is used in an organic light-emitting device.

Aspect 26. A light-emitting device comprising the nano-patterned microlens formed according to the process of any of the preceding aspects.

Aspect 27. A process of fabricating a nano-patterned microlens, the process comprising: (a) forming an imprinting template having patterning features comprising: (i) providing a silicon-containing substrate; (ii) depositing a silicon dioxide film on the substrate; (iii) preparing a self-assembled monolayer on the silicon dioxide film, wherein the monolayer comprises a plurality of nanospheres; (iv) removing portions of the nanospheres in the self-assembled monolayer to form a reduced substrate; (v) depositing a chromium layer on the reduced substrate; (vi) removing the nanospheres to form nanoholes in the reduced substrate; (vii) etching the portion of the silicon dioxide layer that does not have any chromium; (viii) removing the remaining portion of the chromium layer; (viv) applying a hydrophobic surface treatment to the patterned support substrate; (x) applying a curable liquid resin to the patterned support substrate; (xi) curing the liquid resin; and (xii) removing the patterned support substrate from the cured resin thereby forming the imprint template having patterning features; and (b) contacting the imprinting template with a microlens; (c) compressing the imprinting template under a predetermined pressure to imprint the microlens with the imprinting template; and (d) removing the imprinting template to form the nano-patterned microlens.

Aspect 28. The process of aspect 27, wherein the depositing a silicon dioxide film on the substrate includes plasma enhanced chemical vapor deposition.

Aspect 29. The process of aspects 27 or 28, wherein the preparing a self-assembled monolayer on the support substrate comprises forming the self-assembled monolayer on a water surface and transferring the monolayer from the water surface to the support substrate.

Aspect 30. The process of aspect 29, wherein the transferring the monolayer from the water surface includes utilizing a scooping technique.

Aspect 31. The process of aspects 27-30, wherein the self-assembled monolayer comprises polymer nanospheres or inorganic nanopsheres.

Aspect 32. The process of aspect 31, wherein the polymer nanospheres include polystyrene nanospheres.

Aspect 33. The process of aspect 31, wherein the polymer nanospheres include polymethyl methacrylate.

Aspect 34. The process of aspect 31, wherein the inorganic nanospheres comprise SiO₂.

Aspect 35. The process of aspect 31, wherein the polymer nanospheres have diameters ranging from 20 nm to 1000 nm.

Aspect 36. The process of aspect 31, wherein the polymer nanospheres include polystyrene nanospheres having diameters ranging from 20 nm to 1000 nm.

Aspect 37. The process of any one of aspects 27-36, wherein the hydrophobic surface treatment comprises an alkylsilane.

Aspect 38. The process of any one of aspects 27-37, wherein the reducing the monolayer includes using an oxygen-based reactive ion etching process.

Aspect 39. The process of any one of aspects 27-38, wherein the depositing the chromium layer on the patterned substrate includes thermal evaporation.

Aspect 40. The process of any one of aspect 27-39, wherein the patterning features formed include nanorods.

Aspect 41. The process of any one of aspects 27-40, further comprising heating the microlens to a temperature greater than the glass transition temperature of the microlens prior to the compressing step.

Aspect 42. The process of any one of aspects 27-41, wherein the etching the portion of the silicon dioxide layer that does not have chromium disposed thereon includes a reactive ion etching process.

Aspect 43. The process of aspect 42, wherein the reactive ion etching process uses tetrafluoro methane.

Aspect 44. The process of any one of aspects 27-43, wherein the removing the chromium layer includes a wet etching process.

Aspect 45. A process of fabricating a nano-patterned microlens, the process comprising: (a) forming an imprinting template having patterning features comprising: (i) preparing a self-assembled monolayer on a support substrate; (ii) forming a patterned support substrate, wherein the patterned support substrate includes patterning features corresponding to the imprinting template and fabricated nano-patterned microlens; (iii) applying a liquid resin composition to the patterned support substrate and curing the resin composition; and (iv) removing the patterned support substrate from the cured resin composition, thereby forming the imprint template having patterning features; and (b) imprinting a polymeric material with the imprinting template; and (c) removing the imprinting template to form the nano-patterned microlens.

Aspect 46. The process of aspect 45, wherein the imprinting the polymeric material comprises compressing the imprinting template at a predetermined temperature under a predetermined pressure to imprint the polymeric material with the imprinting template.

Aspect 47. The process of aspects 45 or 46, wherein the forming a patterned support substrate includes using a plasma ashing process with oxygen to remove portions of the self-assembled monolayer on the support substrate.

Aspect 48. The process of any of the preceding aspects, further comprising depositing a conformal coating onto the patterned support substrate and applying a hydrophobic surface treatment to the patterned support substrate prior to applying the liquid resin composition.

Aspect 49. The process of aspect 48, wherein the conformal coating comprises Al2O3 or TiO2 and the hydrophobic surface treatment comprises an alkylsilane.

Aspect 50. The process of any of the preceding aspects, wherein the preparing the self-assembled monolayer on the support substrate comprises forming the self-assembled monolayer on a water surface and transferring the monolayer from the water surface to the support substrate using a scooping technique.

Aspect 51. The process of any of the preceding aspects, wherein the self-assembled monolayer comprises polystyrene nanospheres having diameters ranging from 20 nm to 1000 nm.

Aspect 52. The process of any of the preceding aspects, wherein the self-assembled monolayer comprises nanospheres and the removing the portions of the self-assembled monolayer further comprises defining a plurality of interstitial spaces between the nanospheres in the monolayer.

Aspect 53. A process of fabricating a nano-patterned microlens, the process comprising: (a) forming an imprinting template having patterning features comprising: (i) depositing a silicon dioxide film on a substrate; (ii) preparing a self-assembled monolayer on the silicon dioxide film, wherein the monolayer comprises a plurality of nanospheres; (iii) removing portions of the nanospheres in the self-assembled monolayer to form a reduced substrate; (iv) applying a photolithographic mask to the reduced substrate to form a patterned substrate; (v) applying a liquid resin to the patterned substrate and curing the resin; (vi) removing the patterned substrate from the cured resin thereby forming the imprint template having patterning features; and (b) imprinting a microlens with the imprinting template; and (c) removing the imprinting template to form the nano-patterned microlens.

Aspect 54. The process of aspect 53, wherein the applying the photolithographic mask comprises: (a) depositing a chromium layer on the reduced substrate; (b) removing the nanospheres to form nanoholes in the reduced substrate; (c) etching the portion of the silicon dioxide layer that does not have any chromium thereon; and (d) removing the chromium layer to form the patterned substrate.

Aspect 55. The process of aspects 53 or 54, wherein the imprinting the microlens comprises heating the microlens to a temperature greater than the glass transition temperature of the microlens and compressing the imprinting template under a predetermined pressure to imprint the microlens with the imprinting template.

Aspect 56. The process of aspects 53-55, wherein the substrate is a silicon-containing substrate and the depositing the silicon dioxide film on the substrate includes plasma enhanced chemical vapor deposition.

Aspect 57. The process of aspects 53-56, wherein the preparing a self-assembled monolayer on the support substrate comprises forming the self-assembled monolayer on a water surface and transferring the monolayer from the water surface to the support substrate utilizing a scooping technique.

Aspect 58. The process of any one of aspects 53-57, wherein the self-assembled monolayer comprises polystyrene nanospheres having diameters ranging from 20 nm to 1000 nm.

Aspect 59. The process of any one of aspects 53-58, further comprising applying a hydrophobic surface treatment to the patterned support substrate after the applying the photolithographic mask and prior to the applying the liquid resin, wherein the hydrophobic surface treatment comprises an alkylsilane.

Aspect 60. The process of any one of aspects 53-59, wherein the reducing the monolayer includes using an oxygen-based reactive ion etching process.

Aspect 61. The process of any one of aspects 53-60, wherein the etching the portion of the silicon dioxide layer that does not have chromium disposed thereon includes a reactive ion etching process using tetrafluoromethane.

Aspect 62. The process of any one of aspects 53-61, wherein the removing the chromium layer uses a wet etching process.

Aspect 63. A light-emitting device comprising the nano-patterned microlens formed according to the process of any of the preceding aspects.

Aspect 64. A nano-patterned microlens fabricated by a process comprising: (a) forming an imprinting template having patterning features comprising: (i) preparing a self-assembled monolayer on a support substrate; (ii) forming a patterned support substrate, wherein the patterned support substrate includes patterning features corresponding to the imprinting template and fabricated nano-patterned microlens; (iii) applying a liquid resin composition to the patterned support substrate and curing the resin composition; and (iv) removing the patterned support substrate from the cured resin composition, thereby forming the imprint template having patterning features; and (b) imprinting a polymeric material with the imprinting template; and (c) removing the imprinting template to form the nano-patterned microlens.

1. A process of fabricating a nano-patterned microlens, the process comprising:
(a) forming an imprinting template having patterning features comprising:
(i) preparing a self-assembled monolayer on a support substrate;
(ii) forming a patterned support substrate, wherein the patterned support substrate includes patterning features corresponding to the imprinting template and fabricated nano-patterned microlens;
(iii) applying a liquid resin composition to the patterned support substrate and curing the resin composition; and
(iv) removing the patterned support substrate from the cured resin composition, thereby forming the imprint template having patterning features; and
(b) imprinting a polymeric material with the imprinting template; and
(c) removing the imprinting template to form the nano-patterned microlens.

2. The process of claim 1, wherein the imprinting the polymeric material comprises compressing the imprinting template at a predetermined temperature under a predetermined pressure to imprint the polymeric material with the imprinting template.

3. The process of claim 1, wherein the forming a patterned support substrate includes using a plasma ashing process with oxygen to remove portions of the self-assembled monolayer on the support substrate.

4. The process of claim 1, further comprising depositing a conformal coating onto the patterned support substrate and applying a hydrophobic surface treatment to the patterned support substrate prior to applying the liquid resin composition.

5. The process of claim 4, wherein the conformal coating comprises Al₂O₃ or TiO₂ and the hydrophobic surface treatment comprises an alkylsilane.

6. The process of claim 1, wherein the preparing the self-assembled monolayer on the support substrate comprises forming the self-assembled monolayer on a water surface and transferring the monolayer from the water surface to the support substrate using a scooping technique.

7. The process of claim 1, wherein the self-assembled monolayer comprises polystyrene nanospheres having diameters ranging from 20 nm to 1000 nm.

8. The process of claim 1, wherein the self-assembled monolayer comprises nanospheres and the removing the portions of the self-assembled monolayer further comprises defining a plurality of interstitial spaces between the nanospheres in the monolayer.

9. A process of fabricating a nano-patterned microlens, the process comprising:
(a) forming an imprinting template having patterning features comprising:
(i) depositing a silicon dioxide film on a substrate;
(ii) preparing a self-assembled monolayer on the silicon dioxide film, wherein the monolayer comprises a plurality of nanospheres;
(iii) removing portions of the nanospheres in the self-assembled monolayer to form a reduced substrate;
(iv) applying a photolithographic mask to the reduced substrate to form a patterned substrate;
(v) applying a liquid resin to the patterned substrate and curing the resin;
(vi) removing the patterned substrate from the cured resin thereby forming the imprint template having patterning features; and
(b) imprinting a microlens with the imprinting template; and
(c) removing the imprinting template to form the nano-patterned microlens.

10. The process of claim 9, wherein the applying the photolithographic mask comprises:
(a) depositing a chromium layer on the reduced substrate; (b) removing the nanospheres to form nanoholes in the reduced substrate; (c) etching the portion of the silicon dioxide layer that does not have any chromium thereon; and (d) removing the chromium layer to form the patterned substrate.

11. The process of claim 9, wherein the imprinting the microlens comprises heating the microlens to a temperature greater than the glass transition temperature of the microlens and compressing the imprinting template under a predetermined pressure to imprint the microlens with the imprinting template.

12. The process of claim 9, wherein the substrate is a silicon-containing substrate and the depositing the silicon dioxide film on the substrate includes plasma enhanced chemical vapor deposition.

13. The process of claim 9, wherein the preparing a self-assembled monolayer on the support substrate comprises forming the self-assembled monolayer on a water surface and transferring the monolayer from the water surface to the support substrate utilizing a scooping technique.

14. The process of claim 9, wherein the self-assembled monolayer comprises polystyrene nanospheres having diameters ranging from 20 nm to 1000 nm.

15. The process of claim 9, further comprising applying a hydrophobic surface treatment to the patterned support substrate after the applying the photolithographic mask and prior to the applying the liquid resin, wherein the hydrophobic surface treatment comprises an alkylsilane.

16. The process of claim 9, wherein the reducing the monolayer includes using an oxygen-based reactive ion etching process.

17. The process of claim 10, wherein the etching the portion of the silicon dioxide layer that does not have chromium disposed thereon includes a reactive ion etching process using tetrafluoromethane.

18. The process of claim 10, wherein the removing the chromium layer uses a wet etching process.

19. A light-emitting device comprising the nano-patterned microlens formed according to the process of claim 1.

20. A nano-patterned microlens fabricated by a process comprising:
(a) forming an imprinting template having patterning features comprising:
(i) preparing a self-assembled monolayer on a support substrate;
(ii) forming a patterned support substrate, wherein the patterned support substrate includes patterning features corresponding to the imprinting template and fabricated nano-patterned microlens;
(iii) applying a liquid resin composition to the patterned support substrate and curing the resin composition; and
(iv) removing the patterned support substrate from the cured resin composition, thereby forming the imprint template having patterning features; and
(b) imprinting a polymeric material with the imprinting template; and
(c) removing the imprinting template to form the nano-patterned microlens.
